(19) United States
(12) Patent Application Publication
(10) Pub. No.: US 2008/0169827 A1
(43) Pub. Date: Jul. 17, 2008

(54) SENSOR ELEMENT FOR A CAPACITIVE TOUCH SWITCH AND OPERATING DEVICE

(75) Inventor: Ralf Dorwarth, Oberderdingen (DE)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: E.G.O. ELEKTRO-GERAETEBAU GMBH, Oberderdingen (DE)

(21) Appl. No.: 12/014,878

(22) Filed: Jan. 16, 2008

(30) Foreign Application Priority Data
Jan. 16, 2007 (DE) 20 2007 000 969.0

(51) Int. Cl. G01R 27/26

(52) U.S. Cl. 324/661

(57) ABSTRACT

A sensor element for a capacitive touch switch has a sensor element body, which at its first end has a first front face and at a second, other end a second front face and is made from a homogenous elastic material. The shape of the sensor element body diverges from a purely cylindrical shape through recesses and bulges present on its outer contour, the recesses and bulges extending over the length of sensor element body from the first to the second front face. The recesses and bulges are inclined with respect to the median longitudinal axis of the sensor element body so as to form a spiral shape along the outer contour.

### CROSS REFERENCE TO RELATED APPLICATIONS

This application claims priority to German Application Number 20 2007 000 969.0 filed on Jan. 16, 2007, the contents of which are incorporated by reference.

### FIELD OF THE INVENTION

The invention relates to a sensor element for a capacitive touch switch and to an operating device for an electrical appliance having several such sensor elements.

### BACKGROUND OF THE INVENTION

It is known from the prior art, for example US 2005/0248544 or U.S. Pat. No. 5,917,165, to construct sensor elements for a capacitive contact switch with an elastic, electrically conductive sensor element body. A front face, or end of the sensor element body, engages on the underside of an operating surface and forms on said surface a capacitor plate of a capacitor or the functional part of the sensor element. The other front face engages on a support and is electrically contacted. The sensor element body is compressed between the operating surface and the support. In order for an operating device with a plurality of sensor elements not to allow the necessary force for compressing or the total summated spring tension from becoming excessive, an attempt is made in the prior art according to US 2005/0248544 A1 to reduce the spring tension by means of cross holes. However, this constitutes a significant cost factor.

A problem addressed by the invention is to provide an aforementioned sensor element and an aforementioned operating device avoiding the problems of the prior art and in particular, providing a sensor element which can be compressed more easily or with a reduced spring tension.

### BRIEF DESCRIPTION OF THE DRAWINGS

Embodiments of the invention are described hereinafter relative to the attached diagrammatic drawings, wherein:

FIG. 1 illustrates an inclined view of a sensor element according to one embodiment of the invention with a rounded, star-shaped sensor element body cross-section, said body being uniformly twisted over its longitudinal extension;

FIG. 2 illustrates the sensor element of FIG. 1 in the compressed state;

FIG. 3 illustrates an angular, star-shaped cross-section of an alternative sensor element embodiment; and

FIG. 4 illustrates the sensor element of FIGS. 1 and 2 installed in an operating device with a capacitive touch switch.

### DETAILED DESCRIPTION OF THE EMBODIMENTS

In one embodiment, the problems of the prior art is solved by a sensor element having the features of claim 1 and an operating device with several such sensor elements having the features of claim 15. Advantageous and preferred embodiments of the invention form the subject matter of the further claims and are explained in greater detail hereinafter. By express reference the wording of the claims is made into part of the content of the present description.

At a first end, the sensor element body has a first front face and at a second, different end, particularly at the opposite end, a second front face. It is also made from a largely homogeneous material. According to one embodiment of the invention, the shape of the sensor element body diverges from a purely cylindrical shape in that recesses and/or bulges are provided on its outer contour and can be constructed, for example, in the manner of grooves. The recesses and/or bulges extend over and beyond the sensor element body length from the first front face to the second front face and the direction of said extension being inclined to a longitudinal direction of the sensor element body or is inclined to the front faces. Thus, according to one embodiment of the invention, a material reduction not only takes place through recesses between the bulges with the necessarily resulting easier compressibility. As a result of the inclined path of the recesses and/or bulges, it is more easily possible to bring about compression in a direction corresponding to the longitudinal direction of the sensor element body or perpendicular to the front faces than with a straight path. Thus, a type of twisted or turned sensor element body can be created.

In another embodiment of the invention, the aforementioned extension direction of all the recesses and/or bulges has the same inclination angle to the longitudinal axis of the sensor element body or to the front faces. Such an angle can be, for example, 15° to 60°, preferably approximately 20°.

According to a further embodiment of the invention, the sensor element can have a cross-section with a contour or shape diverging from a circle. In the direction between the front faces the sensor element body can have a continuously identical cross-section, but which continuously turns along the longitudinal axis of the sensor element body and in particular turns uniformly about a median longitudinal axis, which gives rise to an aforementioned twisted sensor element body. A turning or rotation angle of such a turn or twist can be at least 30°, advantageously 45° or 60°.

The shape of the cross-section can be regular, for example, in the manner of a star with prongs or rounded bulges and recesses between the bulges. There can be 4 to 10 such prongs or bulges or even more, for example, 6 to 8. The course of the prongs or bulges over and beyond the sensor element body length consequently forms sloping ribs, said ribs being shaped in one piece or integrally on an inner portion of the sensor element body in such a way that it is homogeneous and integral.

The aforementioned prongs or bulges can project, for example, slightly over the intermediate recesses, by 5% to 30% of the diameter. Particularly advantageously, they project between 10% and 20%, so that an adequately large proportion of the sensor element body is distributed over the bulges or the longitudinal ribs formed by them. A proportion of the sensor element body located in the inner area is not negligibly small, so that it still ensures an adequate stability for the sensor element body. Advantageously, the front faces of the sensor element body have an identical construction.

In a another embodiment of the invention, an aforementioned sensor element body can be made from foam rubber or foam, for example, from polymers or elastomers. It is advantageously elastically compressible and electrically conductive, as is known from the prior art. Such a sensor element or sensor element body can be produced by extrusion and during extrusion the aforementioned turning or twisting takes place.

The sensor element body can have a recess between the two front faces in which can be housed, for example, an illuminating means such as an LED. In particularly advantageous manner, such a recess is cylindrical or is provided along the median longitudinal axis and takes up roughly 10 to 20% of a front face. It can have an inner contour which is similar to that of the outer contour or even corresponds thereto and is advantageously also twisted.

In the case of the aforementioned operating device with several aforementioned sensor elements, the latter are placed on a support such as a printed circuit board. Electrical contacting from the support to the sensor elements can take place in the way known from the prior art. On the other front face of the sensor element body is placed a cover or operating surface, and the sensor elements are then compressed and fixed between the cover and the support, or fastened with a predetermined spacing. The sensor elements can be compressed over part of their longitudinal extension, for example 2% to 40%, particularly approximately 20%.

These and other features can be gathered from the claims, description and drawings and the individual features, both singly and in the form of subcombinations, can be implemented in an embodiment of the invention and in other fields and can represent advantageous, independently protectable constructions for which protection is claimed here. The subdivision of the application into individual sections and the subheadings in no way restrict the general validity of the statements made thereunder.

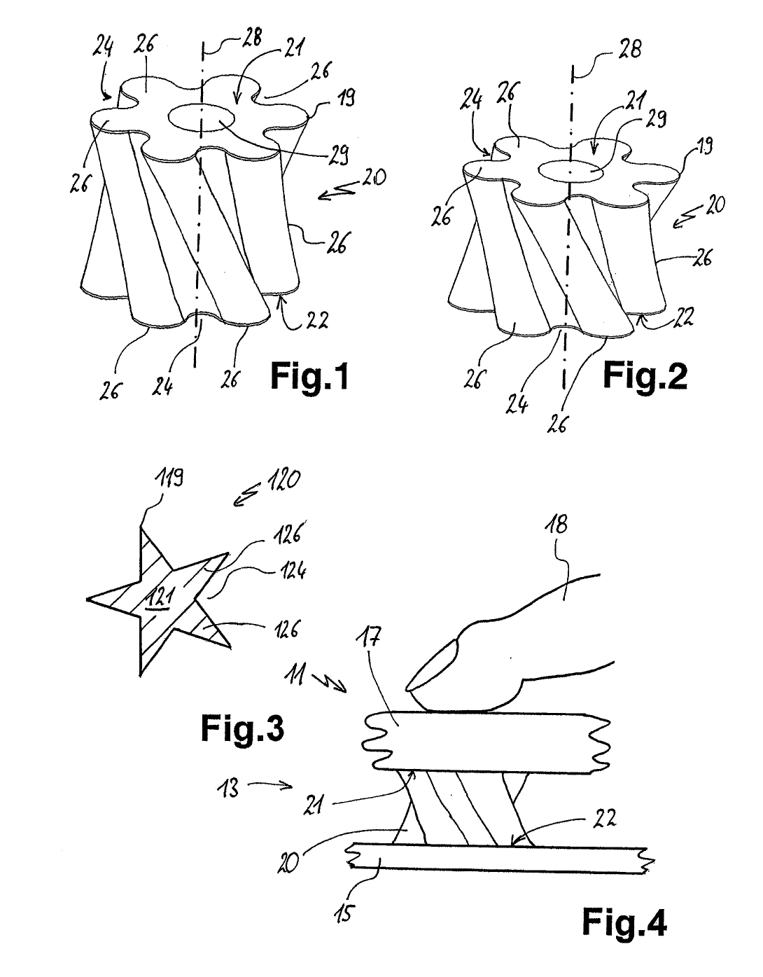

FIG. 1 shows an inventive sensor element 20 with a sensor element body 19, which has a upper front face 21 and a lower front face 22. The front faces 21 and 22 have an identical construction and in each case six uniform recesses 24 and intermediate bulges 26 so that the front face is shaped like a flower or a strongly rounded star. Along a median longitudinal axis 28 shown in dot-dash line form, the sensor element body 19 always has the same cross-sectional surface with the recesses 24 and bulges 26. However, the overall sensor element body 19 is twisted or turned roughly by a rotation angle of 45° over the length of the longitudinal axis. During the manufacture of such a sensor element body 19 from an aforementioned elastic material, this can be brought about by rotating a mould during extrusion or by rotating the long strand following moulding and from which the individual sensor elements 20 are obtained by cutting off.

As can be seen in FIG. 1, the cross-section of the sensor element body and the two front faces 21, 22 are symmetrical and uniformly constructed. Thus, it is possible to fit them without maintaining a specific rotation position, as will be described hereinafter.

A hole 29 as a through bore runs along the median longitudinal axis 28. Said hole 29 can also be produced during the manufacture or extrusion of sensor element 20. As is known from the prior art, it is used for placing an illumination means or LED therein and the latter emits upwards through said hole 29. Said hole 29 also leads to easier compressibility.

FIG. 2 shows sensor element 20 of FIG. 1 in the slightly compressed state, being compressed by roughly 20%. As can be seen, the shape remains essentially the same, the height merely being reduced. Virtually nothing changes on the front faces 21, 22 and in general with regards to the cross-section. As a function of the material for the sensor element 20, a certain widening can take place as a result of compression. With foamed materials, particularly closed-pore materials, an even more pronounced widening can take place.

FIG. 3 shows a modified sensor element 120 in cross-section. The cross-section and front faces have the form of a uniform five-pronged star, the prongs forming the bulges 126 and there are intermediate recesses 124. The sensor element 120 according to FIG. 3 is also turned in accordance with a median longitudinal axis corresponding to the sensor elements of FIGS. 1 and 2, but this is not shown again here.

FIG. 4 shows an operating device 11 with a capacitive touch switch 13. The latter is formed by sensor element 20, whose lower front face 22 engages on the top of a circuit board 15. Its upper front face 21 engages on the bottom of an operating surface 17, for example a glass ceramic plate of a hob, for which the operating device 11 is provided. As is known from the prior art, particularly U.S. Pat. No. 5,917,165 A1, an electrical contacting can take place via an electrically conductive zone on the top of circuit board 15 by means of the lower front face 22 on electrically conductive sensor element 20, which is not shown here. In the vicinity of the contact with the underside of the operating surface 17, the upper front face 21 forms the sensor element surface or a capacitor plate for the capacitive touch switch 13. By applying a finger 18 to the point above the sensor element 20 or above the upper front face 21 operation takes place and this can for example be detected by a control, for example on circuit board 15, which is not shown here and which is connected to sensor element 20.

The essential difference compared with the known sensor elements, for example according to U.S. Pat. No. 5,917,165 A1, is according to FIG. 4 that through the twisting of sensor element 20 or sensor element body 19, the present sensor element can be more easily compressed and thus a reduced force is necessary for this purpose. Further, the necessary material for forming sensor element 20 can also be economized. Through a hole 29 in the centre, a further reduction of the compression force needed is possible. The hole can advantageously be provided with a twisted contour, for example, corresponding to the outer contour of front faces 21 and 22. Compared with a linear cross-section with recesses 24 and bulges 26, twisting offers the advantage that the sensor element 20 can be, so-to-speak, screwed into itself during compression. It has been found in such cases that the necessary force for compression can be significantly reduced compared with a linear cross-section with identical front faces. At the same time, through the shape of the front faces, particularly the upper front face 21, which is important for the capacitive touch switch 13, an adequately large surface can be created for the function of the capacitive touch switch.

1. A sensor element for a capacitive touch switch comprising a sensor element body, said sensor element body having a shape at a first end with a first front face and at a second end with a second front face,
said sensor element body being made from a largely homogeneous material, wherein said shape of said sensor element body diverges from a purely cylindrical shape through recesses and bulges of its outer contour,
said recesses and bulges extending over length-wise along said sensor element body from said first front face to said second front face, wherein an extension direction of said recesses and bulges is inclined at an inclination angle relative to a median longitudinal axis of said sensor element body.

2. The sensor element according to claim 1, wherein said extension direction of all of said recesses and bulges has the same inclination angle relative to said median longitudinal axis of said sensor element body.

3. The sensor element according to claim 1, wherein said sensor element body has a cross-sectional shape diverging from a circle.

4. The sensor element according to claim 3, wherein at any point between said first front face and said second front face, said sensor element body has a non-circular cross-section that is common with said shape.

5. The sensor element according to claim 3, wherein said cross-sectional shape of said sensor element body at a first point along said median longitudinal axis of said body is rotated with respect to a second cross-sectional shape of said sensor body about said median longitudinal axis at a second point along said median longitudinal axis.

6. The sensor element according to claim 3, wherein a first cross-section of said sensor element body is rotated in one direction relative to a second cross-section of said sensor element body.

7. The sensor element according to claim 6, wherein for a plurality of equally spaced cross-sections along said sensor element, the relative rotation of any two consecutive cross-sections is the same.

8. The sensor element according to claim 3, wherein said cross-section of said sensor element body is formed in a manner of a star with bulges and recesses between said bulges.

9. The sensor element according to claim 8, wherein said bulges at any given cross-section project between 5% and 30% of said diameter above said recesses.

10. The sensor element according to claim 6, wherein a relative rotation of said first cross-section of said at said first front face with respect to said second cross-section of said second front face is an angle of at least 30°.

11. The sensor element according to claim 1, wherein said sensor element body is made from a foam rubber material or a foam material, and is elastically compressible and electrically conductive.

12. The sensor element according to claim 11, wherein said sensor element body is made from said foam rubber material that is extruded.

13. The sensor element according to claim 1, wherein a central recess is provided along said median longitudinal axis of said sensor element body in the manner of a long bore.

14. The sensor element according to claim 13, wherein said central recess has an inner contour corresponding to said outer contour of said sensor element body.

15. The sensor element according to claim 3, wherein a plurality of said cross-sectional shape of said sensor element body along said median longitudinal axis of said body between said front faces results in a spiral pattern on the exterior of said sensor element.

16. An sensor element for a capacitive touch switch comprising a sensor element body, said sensor element body having a shape at a first end having a first front face and at a second end having a second front face,
wherein said shape diverges from a purely cylindrical shape through recesses and bulges,
said sensor element body being made from a largely homogeneous foam-based material that is electrically conductive and compressible,
wherein a cross-section of said sensor element body at any point corresponds to said shape, and
wherein a plurality of spiral grooves are formed on the outside of the sensor element body.

17. An operating device for an electrical appliance comprising a plurality of sensor elements, wherein each sensor element comprises a sensor element body, said sensor element body having a shape with a first end with a first front face and a second end with a second front face,
said sensor element body being made from largely homogeneous material, wherein said shape of said sensor element body diverges from a purely cylindrical shape through recesses and bulges of its outer contour,
said recesses and bulges extending over length-wise along said sensor element body from said first front face to said second front face, wherein an extension direction of said recesses and bulges is inclined at an inclination angle relative to a median longitudinal axis of said sensor element body,
wherein said sensor elements are placed on a support beneath a cover, said sensor elements with their front faces being compressed somewhat by a compressive force between said support and said cover.

18. The operating device according to claim 17, wherein said sensor elements with said front faces are compressed together between 2% to 40% between said support and said cover with a compressive force.

19. The operating device according to claim 17, wherein said sensor elements with said front faces are compressed together about 20% between said support and said cover with a compressive force.
